(19) United States
(12) Patent Application Publication
(10) Pub. No.: US 2026/0314442 A1
(43) Pub. Date: Oct. 8, 2026

(54) MULTIFUNCTIONAL EMBEDDED FORMING STRUCTURE FOR MEMORY PACKAGES

(71) Applicant: Sandisk Technologies, Inc., Milpitas, CA (US)

(72) Inventors: Yuanheng Zhang, Shanghai (CN); Jingyun Chen, Shanghai (CN); Shaopeng Dong, Shanghai (CN); Fen Yu, Shanghai (CN); Weng Khoon Mong, Bayan Lepas (MY)

(21) Appl. No.: 19/169,205

(22) Filed: Apr. 3, 2025

(51) Int. Cl. H10W 70/60; H10W 74/10; H10W 90/00; H10B 80/00; H10W 90/24

(52) U.S. Cl. CPC H10W 70/614; H10W 70/611; H10W 74/111; H10W 90/00; H10W 90/401; H10B 80/00; H10W 90/24

(57) ABSTRACT

Examples described herein provide multifunctional embedded forming structures substrate for memory packages. In one example, an embedded forming structure includes a substrate defining a cavity. The substrate is formed using multi-layer forming such that the substrate includes a plurality of layers. Electrical components, such as resistors, capacitors, and inductors may be embedded within the layers during forming of the substrate. Through vias may also be formed in the substrate. The substrate defines a cavity that receives a die, such as a memory die. A supporting structure is formed between the die and the substrate. Electrical interconnects may be formed in the supporting structure that electrically connect the die and the substrate.

### BACKGROUND

The present disclosure relates to storage devices. More particularly, the present disclosure relates to a multifunctional embedded forming structure substrate for memory packages.

The capacity and speed of memory arrangements in data storage devices, such as solid state drives (SSDs), is continually improving as technology advances. Demand for higher processing speeds and smaller advanced microelectronic devices calls reduced package size and lower manufacturing cost. While it is desirable to increase the number of components within a single memory package, the desired performance of the single memory package may be limited by the physical space within the single memory package.

### SUMMARY

For example, maintaining a smaller thickness of the substrate, one of the primary components of the performance and size of memory packages, while improving the performance of memory packages is increasingly difficult. Additionally, for the internal area of the memory packages, wire bonding is commonly implemented to provide efficient interconnection of internal structures. However, the wire bonding process is prone to wire stability problems. In the subsequent molding process, pressure may cause wire-related defects and damage to the internal structure. Traditional wire bonding may also be unable to perform complex multi-angle or micro-area high-density connections.

Examples described herein provide an embedded forming structure (such as a multifunctional embedded forming structure [MEFS]) and methods of forming and assembling (e.g., manufacturing) thereof. The embedded forming structure may include a multi-layer substrate. The multi-layer substrate includes electrical components, such as resistors, capacitors, and inductors, that are embedded within the substrate during formation of the substrate. Electrical interconnects, such as a through vias, may also be formed in the multi-layer substrate to electrically connect the electrical components. The electrical interconnects may also electrically connect the electrical components embedded within the multi-layer substrate to a die, such as a memory die.

In some examples, the multi-layer substrate defines a cavity. A die, such a memory die, may be situated within the cavity. A supporting structure may be formed (for example, by molding or 3D printing) between the die and the multi-layer substrate. The supporting structure may include electrical interconnects to electrically connect the die to the multi-layer substrate.

The disclosure provides an embedded forming structure for a device, the embedded forming structure comprising a substrate defining a cavity. The substrate includes a plurality of layers, a first electrical component embedded within a first layer of the plurality of layers, and a through via.

The disclosure also provides a method of manufacturing an embedded forming structure. The method includes providing a mask on a carrier, providing a cover on the mask, forming a first layer of a substrate on the carrier and around the mask, embedding a first electrical component in the first layer, and forming a second layer of the substrate on the first layer.

The disclosure also provides a memory comprising a first electrical component, a through via, a multi-layer substrate including a plurality of layers, and a memory die within a cavity. The first electrical component and the through via are embedded within a first layer of the plurality of layers. The multi-layer substrate defines the cavity.

In this manner, various aspects of the disclosure provide for improvements in at least the technical fields of memory devices and their design and architecture. The foregoing summary is intended solely to give a general idea of various aspects of the disclosure, and does not limit the scope of the disclosure in any way. Other aspects of the disclosure will become apparent by consideration of the detailed description, the claims, the Abstract, and the accompanying drawings.

### BRIEF DESCRIPTION OF THE DRAWINGS

FIG. 1 is a block diagram illustrating a data storage system, according to embodiments described herein.

FIG. 2 is a flowchart illustrating an example method of forming an MEFS substrate, according to embodiments described herein.

FIG. 3 is a diagram illustrating a first example cross section of an MEFS substrate of FIG. 2, according to embodiments described herein.

FIGS. 4A, 4B, and 4C are diagrams illustrating the formation of a multi-layer substrate in a cavity, according to some embodiments described herein.

FIG. 5 is a diagram illustrating a plurality of layers including embedded electrical components, according to some embodiments described herein.

FIG. 6 is a diagram illustrating a second example cross section of an MEFS substrate of FIG. 2, according to embodiments described herein.

FIG. 7 is a flowchart illustrating an example method of assembling an MEFS, according to embodiments described herein.

FIG. 8 is a diagram illustrating an exploded perspective view of an MEFS substrate, a base layer, and a carrier lamination, according to embodiments described herein.

FIG. 9 is a diagram illustrating a first example cross-sectional view of one window of an MEFS of FIG. 7, according to embodiments described herein.

FIG. 10 is a diagram illustrating a second example cross-sectional view of one window of an MEFS of FIG. 7, according to embodiments described herein.

FIG. 11 is a diagram illustrating a third example cross-sectional view of one window of an MEFS of FIG. 7, according to embodiments described herein.

FIG. 12 is a diagram illustrating a fourth example cross-sectional view of one window of an MEFS of FIG. 7, according to embodiments described herein.

FIG. 13 is a diagram illustrating a fifth example cross-sectional view of one window of an MEFS of FIG. 7, according to embodiments described herein.

FIG. 14 is a diagram illustrating a sixth example cross-sectional view of one window of an MEFS of FIG. 7, according to embodiments described herein.

FIG. 15 is a diagram illustrating a perspective of an example MEFS, according to embodiments described herein.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. It also will be understood by those of skill in the art that the drawings are not to scale, where some features are exaggerated in order to highlight such features.

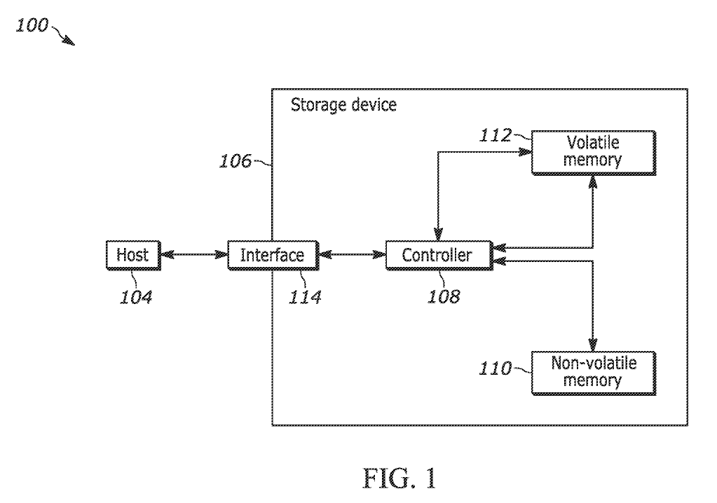

FIG. 1 is a block diagram illustrating a storage system 100 with a storage device 106 that may function in conjunction with a host device 104, in accordance with one or more techniques of this disclosure. For instance, the host device 104 may utilize non-volatile memory devices included in storage device 106 to store and retrieve data.

The storage system 100 includes the host device 104 that may store and/or retrieve data to and/or from the storage device 106. As illustrated in FIG. 1, the host device 104 may communicate with the storage device 106 by way of an interface 114. The host device 104 may comprise any of a wide range of devices, including computer servers, network attached storage (NAS) units, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, and the like.

As illustrated in FIG. 1, the storage device 106 includes a controller 108, non-volatile memory (NVM) 110, volatile memory 112, and an interface 114. In some examples, the storage device 106 may include additional components not shown in FIG. 1 for sake of clarity. For example, the storage device 106 may include a printed circuit board (PCB) to which components of the storage device 106 are mechanically attached and that includes electrically conductive traces that electrically interconnect components of the storage device 106, or the like. In some embodiments, the storage device 106 may include fewer components, for example, where one or more of the volatile memory 112 and the interface 114 are part of the controller 108. In some examples, the physical dimensions and connector configurations of the storage device 106 may conform to one or more standard form factors. Some example standard form factors of the storage device may include 3.5″ data storage device, 2.5″ data storage device, and 1.8″ data storage device. Some example standard form factors of the interface 114 may include peripheral component interconnect (PCI), PCI-extended (PCI-X), and PCI Express (PCIe) (e.g., PCIe x1, x4, x8, x16, PCIe Mini Card, MiniPCl, etc.). In some examples, the storage device 106 may be directly attached (e.g., directly soldered) to a motherboard of the host device 104.

The interface 114 of the storage device 106 may include one or both of a data bus for exchanging data with the host device 104 and a control bus for exchanging commands with the host device 104. The interface 114 may operate in accordance with any suitable protocol. For example, the interface 114 may operate in accordance with one or more of the following protocols: advanced technology attachment (ATA) (e.g., serial-ATA (SATA) and parallel-ATA (PATA)), Fibre Channel Protocol (FCP), small computer system interface (SCSI), serially attached SCSI (SAS), PCI, and PCIe, non-volatile memory express (NVMe), OpenCAPI, GenZ, Cache Coherent Interface Accelerator (CCIX), or the like. The interface 114 is communicatively connected (e.g., a data bus, a control bus, or other suitable connection) to the controller 108, allowing data to be exchanged between the host device 104 and the controller 108. In some examples, the interface 114 may also permit the storage device 106 to receive power from the host device 104.

The NVM 110 may be part of a packaged integrated circuit (IC) or other packaged silicon device, such as a memory device. The NVM 110 may also include read/write circuitry that reads data from and writes data to another portion of the memory device. For instance, the read/write circuitry of the NVM 110 may receive data and a message from the controller 108 that instructs the read/write circuitry to store the data in the NVM 110. Similarly, the read/write circuitry of the NVM 110 may receive a message from the controller 108 that instructs the read/write circuitry to retrieve data from the NVM 110. In some examples, each die (i.e., the controller 108 and memory dies making up the NVM 110 of the memory device) may be individually referred to as a silicon die.

In some examples, the memory device may include any type of non-volatile memory. For example, the NVM 110 may include flash memory or any other suitable non-volatile memory. Flash memory may include NAND-based or NOR-based flash memory, and may store data based on a charge contained in a floating gate of a transistor for each flash memory cell. In NAND-based flash memory, the flash memory may be divided into a plurality of blocks that may divided into a plurality of pages. Each block of the plurality of blocks may include a plurality of NAND cells. Rows of NAND cells may be electrically connected using a word line to define a page of a plurality of pages. Respective cells in each of the plurality of pages may be electrically connected to respective bit lines. Furthermore, the NAND-based flash memory may be 2D or 3D, and may be configured as a single-level cell (SLC) memory, a multi-level cell (MLC) memory, a triple-level cell (TLC) memory, or a quad-level cell (QLC) memory.

The volatile memory 112 may be used by the controller 108 to store information. The volatile memory 112 may be comprised of one or more volatile memory devices. In some examples, the controller 108 may use the volatile memory 112 as a cache. For instance, the controller 108 may store cached information in the volatile memory 112 until the cached information is written to the NVM 110. Examples of the volatile memory 112 include, but are not limited to, random-access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)).

The controller 108 manages one or more operations of the storage device 106. For instance, the controller 108 manages the reading of data from and/or the writing of data to the NVM 110. In some embodiments, when the storage device 106 receives a write command from the host device 104, the controller 108 may initiate a data storage command to store data to the NVM 110 and monitor the progress of the data storage command. In other embodiments, the controller 108 may determine at least one operational characteristic of the storage system 100 and store the at least one operational characteristic in the NVM 110.

Examples described herein provide for the formation of cavity substrates with embedded components, such as embedded resistors, inductors, and capacitors. Aspects described herein may provide for thin substrates for packages, such as memory packages, by implementing a multifunctional embedded forming structure (MEFS). Examples of the MEFS described herein provide a substrate surrounding a die, providing for thinner and smaller memory packages compared to those currently on the market. The die may be a memory die or a controller die.

Examples of the MEFS described herein utilize multi-layer forming, embedding electrical components within the substrate. Electrical connection of the die with the surrounding substrate and protection of the internal structure are also achieved using multi-layer forming. For example, defects caused by wire stability during wire bonding, and mold flow (or pressure) during molding processes are avoided. By embedding electrical pathing using multi-layer forming, right-angle, corner, vertical, and horizontal pathing can be achieved that cannot be accomplished with traditional bonding wires.

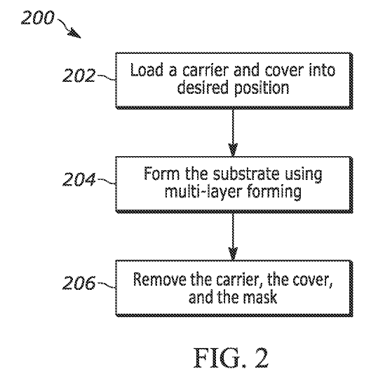

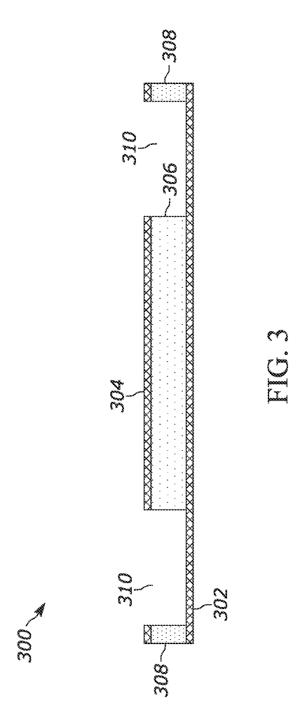

FIG. 2 is a flowchart illustrating an example method 200 of forming an MEFS substrate. FIGS. 3-6 illustrate an example MEFS substrate 300 with respect to the example method 200. The method 200 includes loading a carrier and cover into a desired position (at block 202). For example, with reference to FIG. 3, the MEFS substrate 300 includes a carrier 302 and a cover 304. The carrier 302 supports a mask 306 and prepreg material 308. The prepreg material 308 is situated on opposing ends of the carrier 302. The mask 306 and the prepreg material 308 are separated by a cavity 310. The cover 304 is situated on both the mask 306 and the prepreg material 308.

The method 200 includes forming the substrate using multi-layer forming (at block 204). For example, the substrate of the MEFS substrate 300, including electrical pathways, is formed using different materials with forming path and area design. Electrical components including any combination of resistors, capacitors, and/or inductors are embedded into corresponding substrate locations. The structure of levels may vary. For example, a resistive powder film may be added to achieve a particular resistance value, or heat-conducting structures such as embedded thermal micro-vias may be formed as the interconnects between layers to enhance thermal management. As one example, the thermal micro-vias may be holes that establish a low thermal resistance path through the substrate.

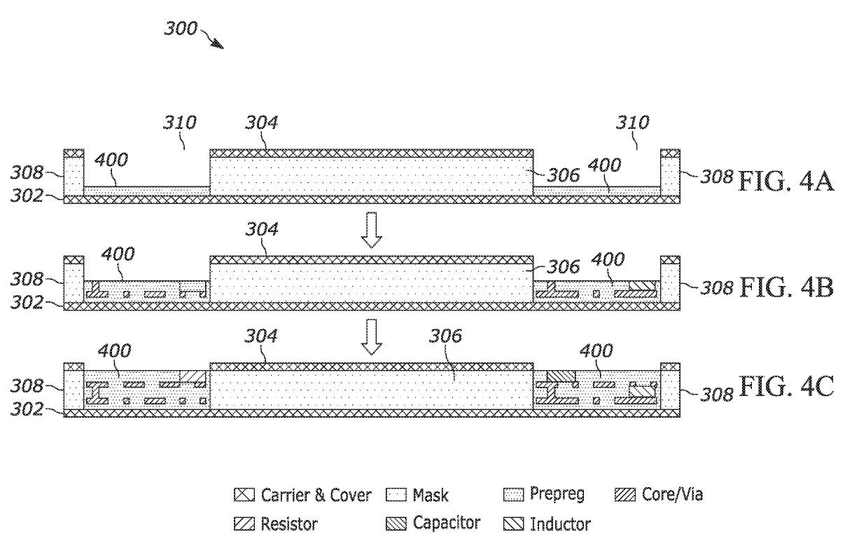

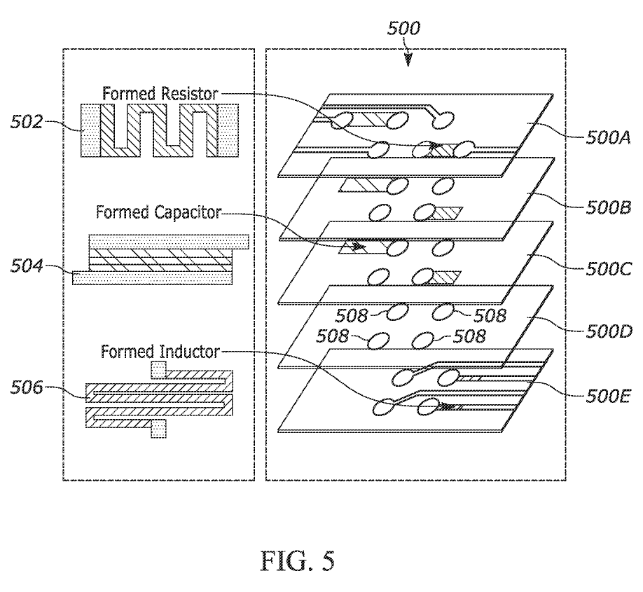

FIGS. 4A, 4B, and 4C are diagrams illustrating the formation of a multi-layer substrate 400 in the cavity 310. Forming the substrate 400 may include 3D printing the substrate 400. In FIG. 4A, a first layer of the substrate 400 is formed on the carrier 302. In FIG. 4B, multiple layers are formed on the first layer of the substrate 400, including vias (e.g., electrical connections or electrical pathways) and embedded components such as resistors, inductors, and/or capacitors. In FIG. 4C, the multi-layer substrate 400 is fully formed. A height of the multi-layer substrate 400 may be approximately equal to a height of the mask 306. Each thin layer of the multi-layer substrate 400 may be formed using a material such as flame-retardant resins, metals, ceramics, glass fibers, alumina, beryllium oxide, aluminum nitride, boron nitride, borosilicate, fused silica, polyimide, Teflon, polyester-based polymers, polytetrafluoroethylene, epoxy, or other suitable materials.

FIG. 5 is a diagram illustrating a plurality of layers 500A–500E (collectively “a plurality of layers 500”) including embedded components. The embedded components include a resistor 502, a capacitor 504, and an inductor 506. Each embedded component may be situated on a single layer or may be spread over multiple layers of the plurality of layers 500. Additionally, each layer of the plurality of layers 500 may be manufactured differently based on whether the layer includes the resistor 502, the capacitor 504, the inductor 506, through vias, or combinations thereof. For example, when the resistor 502 is formed, sheet type resistors may be implemented. For instances with high resistance, interrupted forming patterns may be applied during the resistor film manufacturing process to increase the resistance. The resistor 502 may also be formed using metal materials mixed with organic chemical filters, metal oxide powders, or slurries of glass and metal particles.

When the capacitor 504 is implemented, multi-layer manufacturing may be performed using powdered materials with high dielectric constants. The capacitor 504 may be formed using high dielectric constant materials such as ceramic filter, perovskite powder, filled polymer, or the like. The capacitor 504 may also include a thin dielectric thickness for embedded in the substrate 400. Epoxy, polyimide, polytetrafluoroethylene, and the like may be utilized as dielectric supports.

In the example of FIG. 5, the plurality of layers 500 includes a first layer 500A, a second layer 500B, a third layer 500C, a fourth layer 500D, and a fifth layer 500E. The plurality of layers 500 may be sequentially formed such that the first layer 500A is formed directly above the second layer 500B, the second layer 500B is formed directly above the third layer 500C, the third layer 500C is formed directly above the fourth layer 500D, and the fourth layer 500D is formed directly above the fifth layer 500E. The fifth layer 500E may contact the carrier 302. In other examples, the plurality of layers 500 include fewer or more layers than those illustrated in FIG. 5. In these examples, the plurality of layers 500 may also be formed in a different order than the order illustrated in FIG. 5.

The embedded components may be situated on a single layer or may be formed over multiple layers. For example, in FIG. 5, the inductor 506 is formed in the fifth layer 500E. The capacitor 504 is formed within the first layer 500A, the second layer 500B, and the third layer 500C. The resistor 502 is formed within the first layer 500A, the second layer 500B, and the third layer 500C. Through vias 508 (e.g., electrical interconnects) are formed in the plurality of layers 500 to electrically connect each layer and the embedded components. In FIG. 5, the through vias 508 are only labelled in the fourth layer 500D for sake of clarity.

By forming the substrate 400 layer by layer, utilization of the vertical direction, and the entire usable volume of the substrate 400, is increased, allowing for more layers of routing and embedded components. In this manner, the through vias 508 may include 90° corners between travel in the vertical direction to travel in the horizontal direction and vice versa.

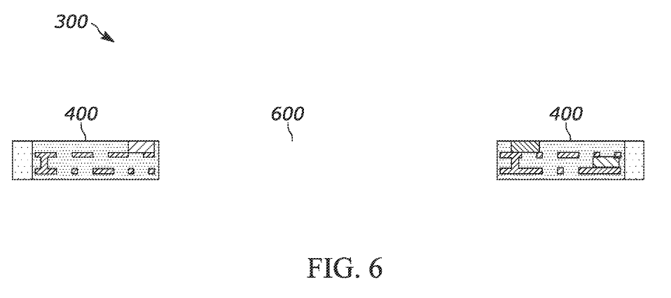

Returning to FIG. 2, the method 200 includes removing the carrier 302, the cover 304, and the mask 306 (at block 206). For example, FIG. 6 illustrates an example of the MEFS substrate 300 with the carrier 302, the cover 304, and the mask 306 removed. When the mask 306 is removed, the walls of the multi-layer substrate 400 define a cavity 600. The cavity 600 is the space in which the mask 306 was previously provided.

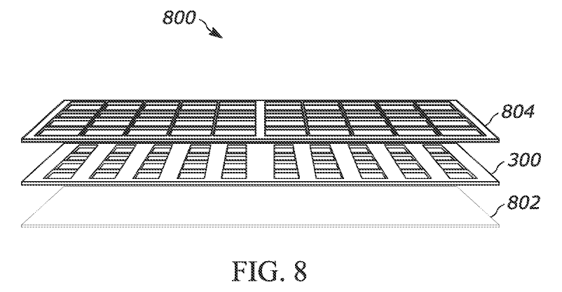

The MEFS substrate 300 illustrated in FIGS. 3-6 may be a single portion of a window substrate (shown in FIG. 8). For example, the MEFS substrate 300 may include a plurality of cavities 600, each cavity 600 surrounded by the multi-layer substrate 400.

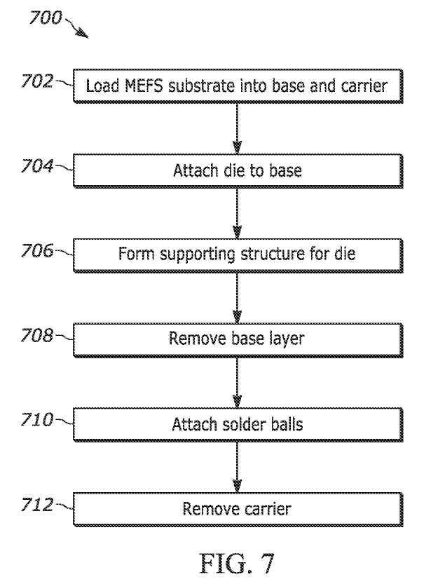

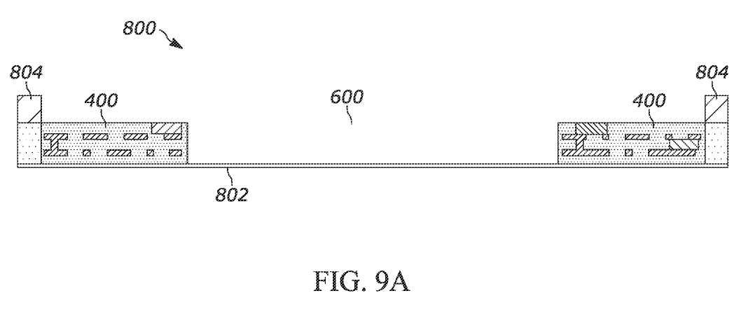

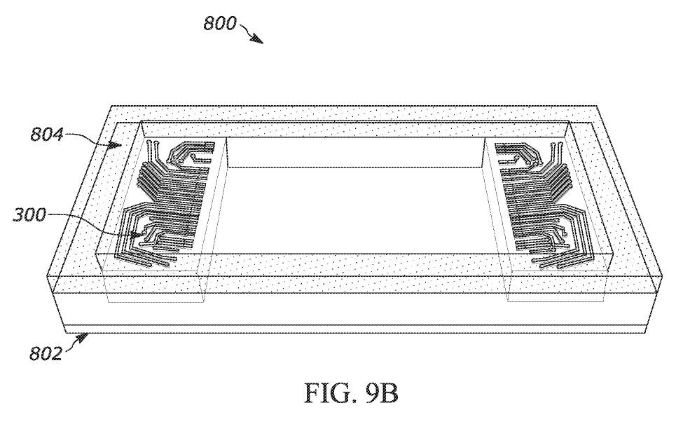

FIG. 7 is a flowchart illustrating an example method 700 of assembling an MEFS. FIGS. 8-15 illustrate an example MEFS 800 with respect to the method 700. The method 700 includes loading the MEFS substate 300 into a base and carrier (at block 702). For example, FIG. 8 illustrates the MEFS 800 including the MEFS substrate 300 (e.g., the MEFS substrate 300 formed by method 200), a base layer 802, and a carrier lamination 804. In the example of FIGS. 8-15, the MEFS substrate 300 is a window substrate having a plurality of windows (e.g., plurality of cavities 600). FIG. 9A is a diagram illustrating a cross-sectional view of one window of the MEFS 800. FIG. 9B is a perspective view of one window of the MEFS 800. In the example of FIGS. 9A and 9B, the multi-layer substrate 400 is sandwiched between the base layer 802 and the carrier lamination 804. In the example of FIGS. 9A and 9B, the MEFS substrate 300 is only situated on two sides of the cavity 600. In other examples, the MEFS substrate 300 may be situated on more than two sides of the cavity 600 (for example, four sides of the cavity 600).

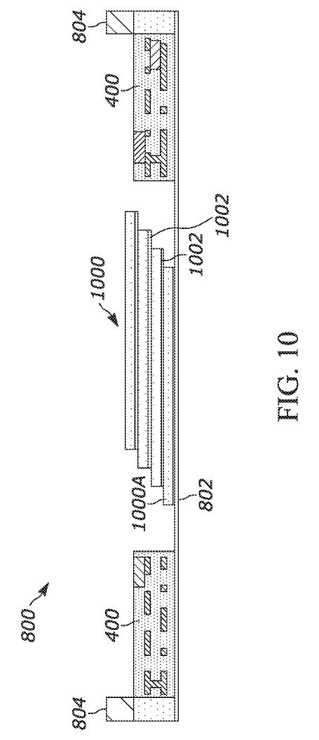

The method 700 includes attaching a die to the base layer 802 (at block 704). For example, with reference to FIG. 10, a plurality of memory dies 1000 are placed within the cavity 600. In this manner, the plurality of memory dies 1000 replace the mask 306 within the cavity 600. A first memory die 1000A of the plurality of memory dies 1000 is physically connected to the base layer 802 (for example, using an adhesive). Each die of the plurality of memory dies 1000 may be stacked offset from the die directly beneath, resulting in overhang portions 1002. While the plurality of memory dies 1000 is illustrated in FIG. 10, in some implementations, only a single memory die (e.g., only first memory die 1000A) may be provided on the base layer 802. In other examples, one or more controller dies are provided on the base layer 802. In yet a further example, one window of the MEFS substrate 800 includes a memory die, while another window of the MEFS substrate 800 includes a controller die.

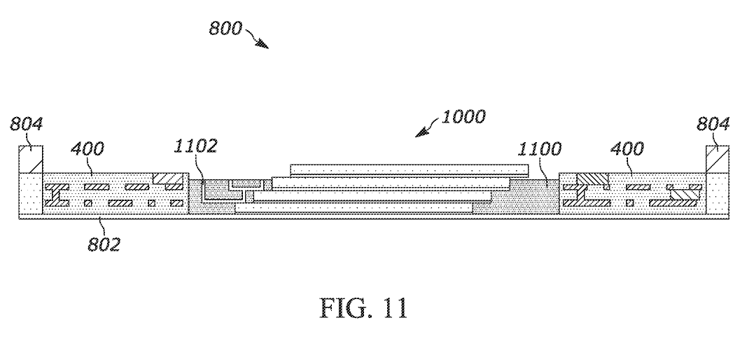

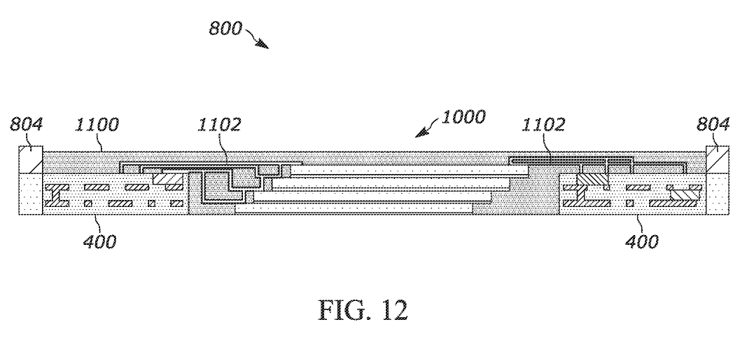

The method 700 includes forming a supporting structure for the die (at block 706). For example, with reference to FIG. 11, supporting material 1100 is formed between the plurality of memory dies 1000 and the multi-layer substrate 400. The supporting material 1100 may be formed by injection molding, 3D printing, or similar techniques. The supporting material 1100 may fully encapsulate the plurality of memory dies 1000 and the multi-layer substrate 400 (as illustrated in FIG. 12). The supporting material 1100 may be, for example, epoxy resin, an organic polymer, an inorganic filler, or a similar material. In some implementations, the supporting material 1100 is formed layer by layer (where each memory die of the plurality of memory dies 1000 correspond to a single layer). In this manner, each memory die of the plurality of memory dies 1000 is interconnected and protected layer by layer.

The supporting material 1100 includes electrical interconnects 1102 that electrically connect each of the memory dies in the plurality of memory dies 1000. The electrical interconnects 1102 may be, for example, through vias. The electrical interconnects 1102 also electrically connect the plurality of memory dies 1000 to the multi-layer substrate 400 (shown in FIG. 12). The electrical interconnects 1102 may be composed of gold or other metal powders and polymer-based materials (for example, phenolic resin) such that the electrical interconnects 1102 and the supporting material 1100 are formed layer-by-layer simultaneously.

The method 700 includes removing the base layer (at block 708). For example, with reference to FIG. 12, the base layer 802 is removed from the MEFS 800. In some instances, removing the base layer 802 also includes removing the prepreg material 308.

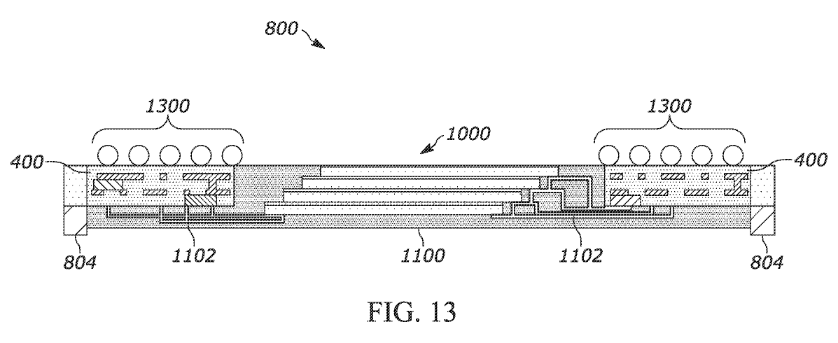

The method 700 includes attaching solder balls (at block 710). For example, with reference to FIG. 13, solder balls 1300 are deposited on the substrate 400. In some instances, depositing the solder balls 1300 includes flipping the MEFS 800 to access the bottom of the substrate 400.

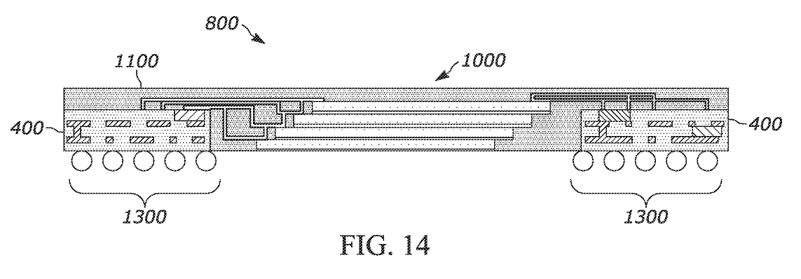

The method 700 includes removing the carrier (at block 712). For example, with reference to FIG. 14, the carrier lamination 804 is removed from the MEFS 800.

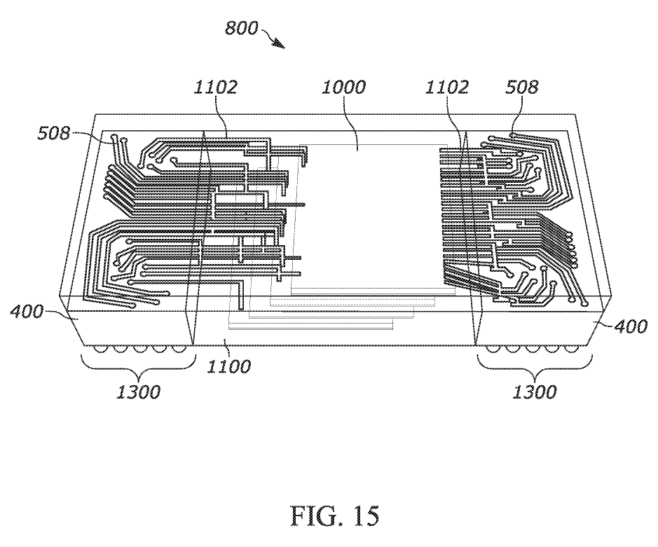

FIG. 15 illustrates an example of the assembled MEFS 800. In the MEFS 800, the plurality of memory dies 1000 are encapsulated by the supporting material 1100. The electrical interconnects 1102 are also provided within the supporting material 1100 and electrically connect the plurality of memory dies 1000 to the substrate 400. For example, the electrical interconnects 1102 connect to the through vias 508 in the substrate 400. In the example of FIG. 15, the electrical interconnects 1102 connect to a top portion of the substrate 400 (e.g., a side of the substrate 400 opposite the solder balls 1300). The substrate 400 and the plurality of memory dies 1000 are situated on a same plane, providing for a thinner package compared to packages that place a substrate beneath or above dies.

While the foregoing is directed to embodiments of the present disclosure, other and further embodiments of the disclosure may be devised without departing from the basic scope thereof. The scope of the present disclosure should be determined by the following claims.

What is claimed is:

1. An embedded forming structure for a device, the embedded forming structure comprising:
a substrate defining a cavity, the substrate including:
a plurality of layers,
a first electrical component embedded within a first layer of the plurality of layers, and
a through via.

2. The embedded forming structure of claim 1, wherein the substrate further includes:
a second electrical component embedded within a second layer of the plurality of layers, wherein the through via electrically connects the first electrical component and the second electrical component.

3. The embedded forming structure of claim 1, wherein the first electrical component is embedded within the first layer and a second layer of the plurality of layers.

4. The embedded forming structure of claim 1, further comprising:
a die within the cavity, the die electrically connected to the through via.

5. The embedded forming structure of claim 4, further comprising:
a supporting material formed between the die and the substrate.

6. The embedded forming structure of claim 1, wherein the substrate is a window substrate defining a plurality of cavities.

7. A method of manufacturing an embedded forming structure, the method comprising:
providing a mask on a carrier;
providing a cover on the mask;
forming a first layer of a substrate on the carrier and around the mask;
embedding a first electrical component in the first layer; and
forming a second layer of the substrate on the first layer.

8. The method of claim 7, further comprising:
providing prepreg material at opposing ends of the carrier.

9. The method of claim 7, further comprising:
removing the mask from the carrier, wherein, when the mask is removed from the carrier, the substrate defines a cavity.

10. The method of claim 9, further comprising:
providing a die within the cavity; and
forming a supporting structure for the die.

11. The method of claim 10, wherein forming the supporting structure for the die includes forming interconnects that electrically connect the die and the substrate together.

12. The method of claim 10, further comprising:
removing the carrier from the substrate.

13. The method of claim 10, wherein the substrate defines a plurality of cavities, wherein the cavity is a first cavity of the plurality of cavities, wherein the die is a first die, and wherein the method further includes:
providing a second die within a second cavity of the plurality of cavities.

14. The method of claim 13, wherein the first die is a memory die, and wherein the second die is a controller die.

15. The method of claim 7, further comprising:
embedding a second electrical component within the second layer,
wherein the substrate further includes a through via electrically connecting the first electrical component and the second electrical component together.

16. The method of claim 7, further comprising:
embedding the first electrical component within the second layer.

17. The method of claim 7, wherein the first electrical component is one of a resistor, a capacitor, or an inductor.

18. A memory comprising:
a first electrical component;
a through via;
a multi-layer substrate including a plurality of layers, wherein the first electrical component and the through via are embedded within a first layer of the plurality of layers, and wherein the multi-layer substrate defines a cavity; and
a memory die within the cavity.

19. The memory of claim 18, further comprising a second memory die, wherein the multi-layer substrate further includes a second cavity, and wherein the second memory die is within the second cavity.

20. The memory of claim 18, wherein the multi-layer substrate further includes a second electrical component embedded within a second layer of the plurality of layers, and wherein the first electrical component is embedded within the first layer and the second layer of the plurality of layers.
